(19) United States
(12) Patent Application Publication
(10) Pub. No.: US 2002/0070436 A1
(43) Pub. Date: Jun. 13, 2002

(54) Die pad for integrated circuits

(76) Inventors: Chong Chin Hui, Tao Payoh (SG); Lee Teck Yeow, Singapore (SG); Chen Fung Leng, Singapore (SG); Rahul Kapoor, Casafina (SG)

Correspondence Address: TEXAS INSTRUMENTS INCORPORATED, P O BOX 655474, M/S 3999, DALLAS, TX, 75265

(21) Appl. No.: 09/982,595

(22) Filed: Oct. 18, 2001

Related U.S. Application Data
(60) Provisional application No. 60/254,567, filed on Dec. 11, 2000.

(51) Int. Cl. H01L 23/02

(52) U.S. Cl. 257/678

(57) ABSTRACT

Die pads are provided which reduce moisture retention and thermal mismatch by employing a number of die pad sections or a die pad support portion with a number of relief regions. In each case, the die pad area to die area ratio is reduced to improve the thermal mismatch between the die and the die pad. Also, the die pad sections or relief regions are arranged in a spaced apart fashion to provide moisture escape paths between the die and the die pad.

### TECHNICAL FIELD OF THE INVENTION

This invention relates generally to the field of integrated circuits, and more particularly to die pads which minimize cracking in integrated circuit packaging.

### BACKGROUND OF THE INVENTION

FIG. 1A illustrates a cross sectional view of a conventional integrated circuit fabrication. In this arrangement a semiconductor die 102 is affixed to a die pad 104 and bond wires (not shown) are attached between the die 102 and leads 106. The die 102, die pad 104, and leads 106 are then encapsulated with a molding resin to form the body of the integrated circuit package 108.

This packaging method experiences known problems related to the capture of moisture within the package as well as from thermal mismatches between the die pad 104 and the die 102. Each of these conditions can lead to device stress and cracking, especially during moisture soak and reflow soldering processes. For example, if moisture is captured in a region 110 proximate the die pad 104, when subjected to the heat of reflow soldering, this moisture can expand and result in package deformation 112. As shown in FIG. 1C, such deformation can result in failure of the package by way of cracks 114.

In addition to moisture entrapment, package stress and failure can also result from a thermal mismatch between the die 102 and the die pad 104. In this case, as the integrated circuit is subjected to rapid changes in temperature, a substantially different rate of expansion/contraction between the die pad 104 and die 102 will result in induced stress. This stress can be sufficient such that the die 102 delaminates from the die pad 104. Failure of the package as shown in FIG. 1 C can be the result of such thermal stresses.

To minimize these known phenomenon, it is desirable to provide an integrated circuit packaging arrangement which minimizes moisture entrapment and thermal mismatch between the die and the die pad.

### SUMMARY OF THE INVENTION

Accordingly, there remains a need for improved die pads and die pad configurations which minimize thermal mismatch and moisture capture in integrated circuit devices.

In accordance with the invention, a die pad configuration for an integrated circuit having an integrated circuit die is provided. The die pad includes a number of die pad regions for supporting the integrated circuit die. The die pad regions are arranged in a spaced apart relationship with respect to the die, thereby providing moisture escape paths. Each die pad region has an associated area. The total area of the die pad regions is at most equal to about fifty percent (50%) of the area of the die.

The die pad configuration can include four die pad regions. In this case, it is preferable that the four die pad regions are spaced apart such that they are each proximate to a comer of the die.

Alternatively, the die pad can include two die pad regions, with the two die pad regions preferably being spaced such that they are each proximate to an opposing edge of the die.

In another embodiment, a die pad for an integrated includes a central support portion for supporting an integrated circuit die. The support portion includes a number of regions of relief therein, which are arranged in a spaced apart relationship with respect to the die. The support portion has a total area being at most equal to about forty percent (40%)of the area of the die.

The relief regions can include four relief regions which are located near the comers of the die. Alternately, the relief regions can include two regions which are located near two opposing edges of the die.

Other technical advantages of the present invention will be readily apparent to one skilled in the art from the following figures, descriptions, and claims.

### BRIEF DESCRIPTION OF THE DRAWINGS

For a more complete understanding of the present invention, and advantages thereof, reference is now made to the following description taken in conjunction with the accompanying drawings, wherein like reference numerals represent like parts, in which:

FIGS. 1A through 1C are schematic diagrams illustrating, in cross section, an exemplary prior art integrated circuit package;

FIG. 2 is a top plan view illustrating a four pad die pad in accordance with the present invention;

FIG. 3 is a cross sectional view along line 3-3 of the four pad die pad of FIG. 2;

FIG. 4 is a top plan view illustrating a two pad die pad in accordance with the present invention;

FIG. 5 is a cross sectional view along line 5-5 of the two pad die pad of FIG. 4;

FIG. 6 is a top plan view illustrating an alternate embodiment of a die pad having a central support region and four relief regions in accordance with the present invention;

FIG. 7 is a top plan view illustrating an alternate embodiment of a die pad having a central support region and two relief regions in accordance with the present invention; and

FIG. 8 is a cross sectional view of the die pad of FIG. 7 along section line 8-8.

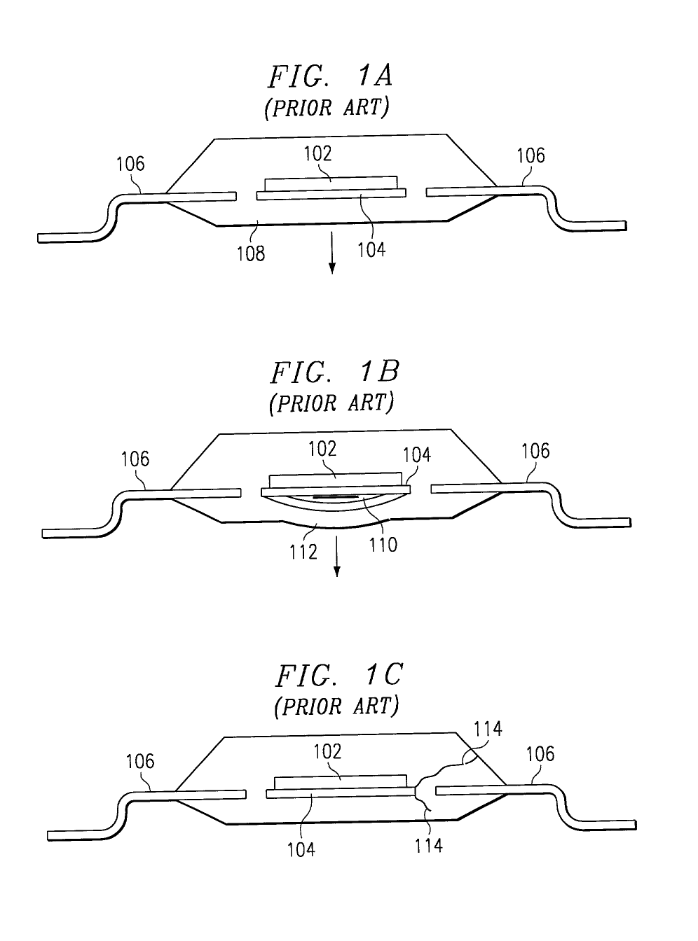

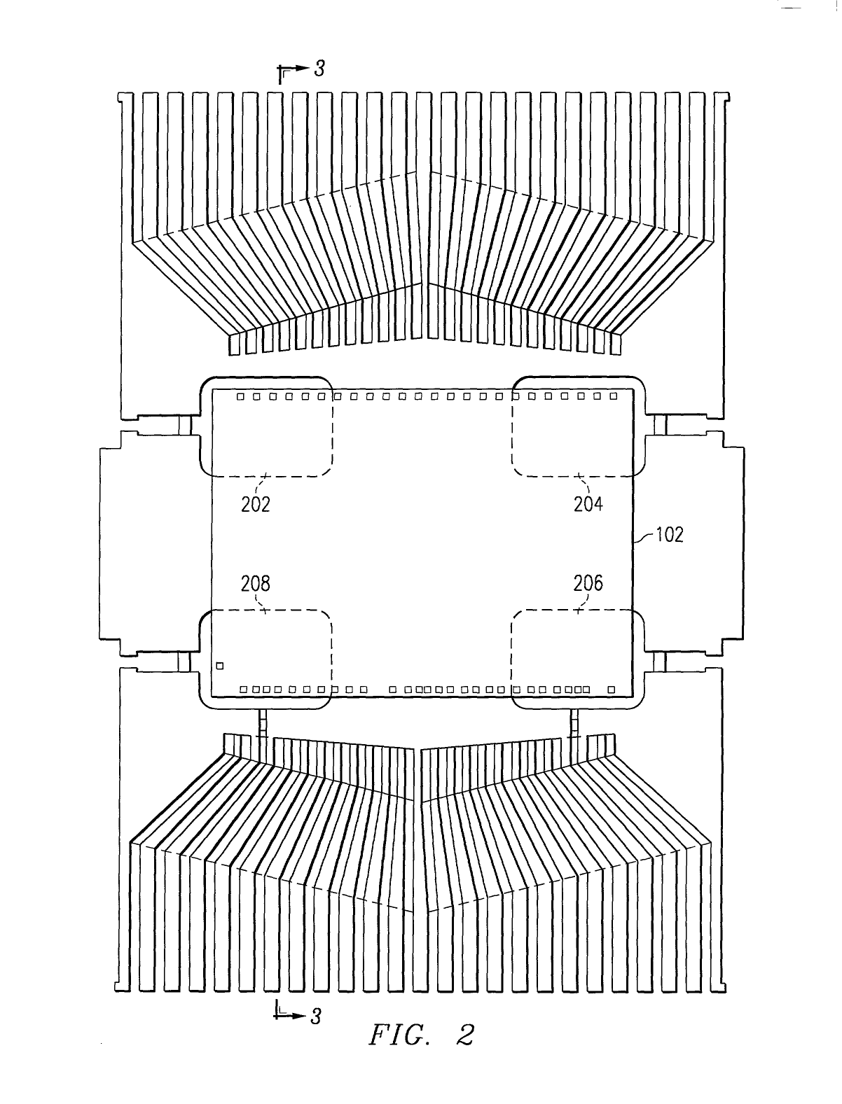

### DETAILED DESCRIPTION OF THE INVENTION

The preferred embodiments of the present invention and its advantages are best understood by referring now in more detail to the drawings, in which like numerals refer to like parts.

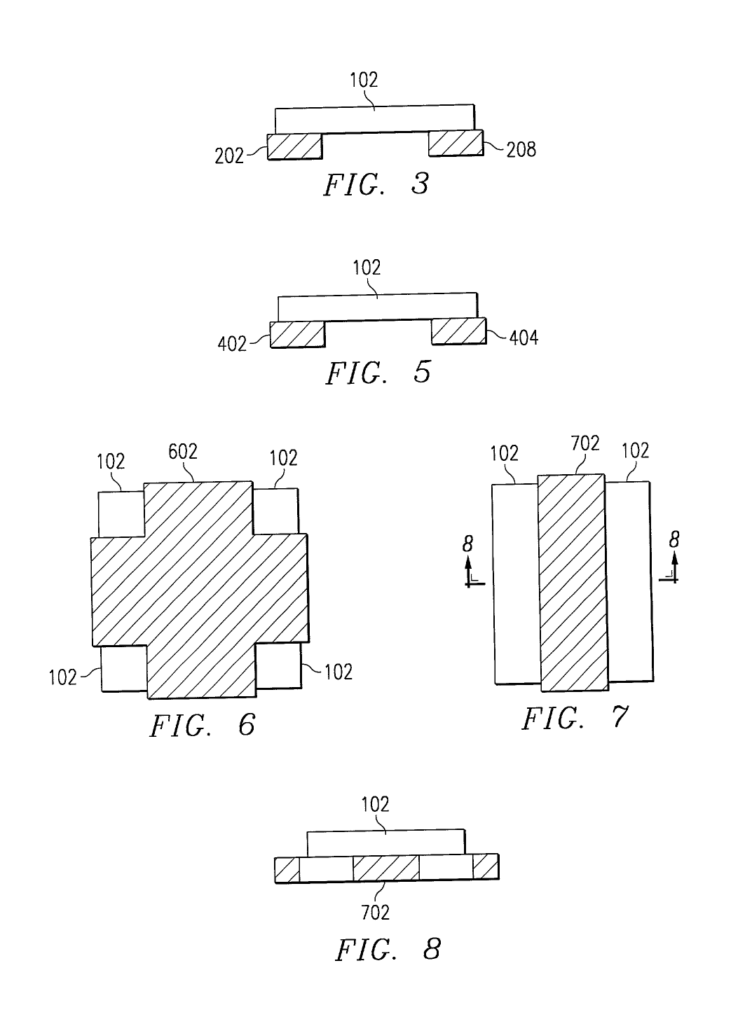

FIG. 2 is a top plan view illustrating a four pad die pad in accordance with the present invention. Unlike conventional die pads, the die pad in FIG. 2 is not a single rectangular area. To the contrary, the die 102 is supported proximate each comer by four die pad sections 202, 204, 206 and 208. This is illustrated in the cross sectional view of FIG. 3, which is taken along line 3-3 in FIG. 2. As is illustrated in FIGS. 2 and 3, the arrangement of four die pad sections provides a die pad with substantially less surface area than the die. This reduction in die pad area to die area ratio minimizes thermal mismatch and the resulting stresses therefrom. In addition, the spaced apart placement of the four die pad sections provides significant moisture escape paths and minimizes the surface area between the die pad and die where moisture can be trapped. Preferably the die pad area to die area ratio is in the range of a minimum of about 0.3 and a maximum of about 0.50. For example, in the case of a 48 lead TSOP packaging design for a die size of about 0.255×0.338 inches, each die pad section 202, 204, 206, 208, can be formed as a rectangle having the dimensions 0.074×0.095 resulting in a die pad to die area ratio of 0.326. FIGS. 4 and 5 illustrate an alternate embodiment of a die pad configuration which also improves thermal mismatch and moisture capture properties. Referring to FIG. 4, which is a top plan view, it is apparent that instead of four rectangular regions proximate the corners of the die 102, the die pad can take the form of two rectangular die pad sections 402, 404 which are proximate to two opposing edges of the die pad 102. As in the case of four die pad sections, the use of two rectangular die pad sections also provides a die pad with substantially less surface area than the die. This reduction in die pad area to die area ratio minimizes thermal mismatch and the resulting stresses therefrom. In addition, the spaced apart placement of the two die pad sections provides a significant central moisture escape path and reduces the surface area between the die pad and die where moisture can be trapped. Preferably the die pad area to die area ratio is in the range of about 0.40 to about 0.50. For example, in the case of a 48 lead TSOP packaging design for a die size of about 0.255×0.338 inches, each die pad section 402, 404 can be formed as a rectangle having the dimensions 0.054 ×0.358 resulting in a die pad to die area ratio of 0.45.

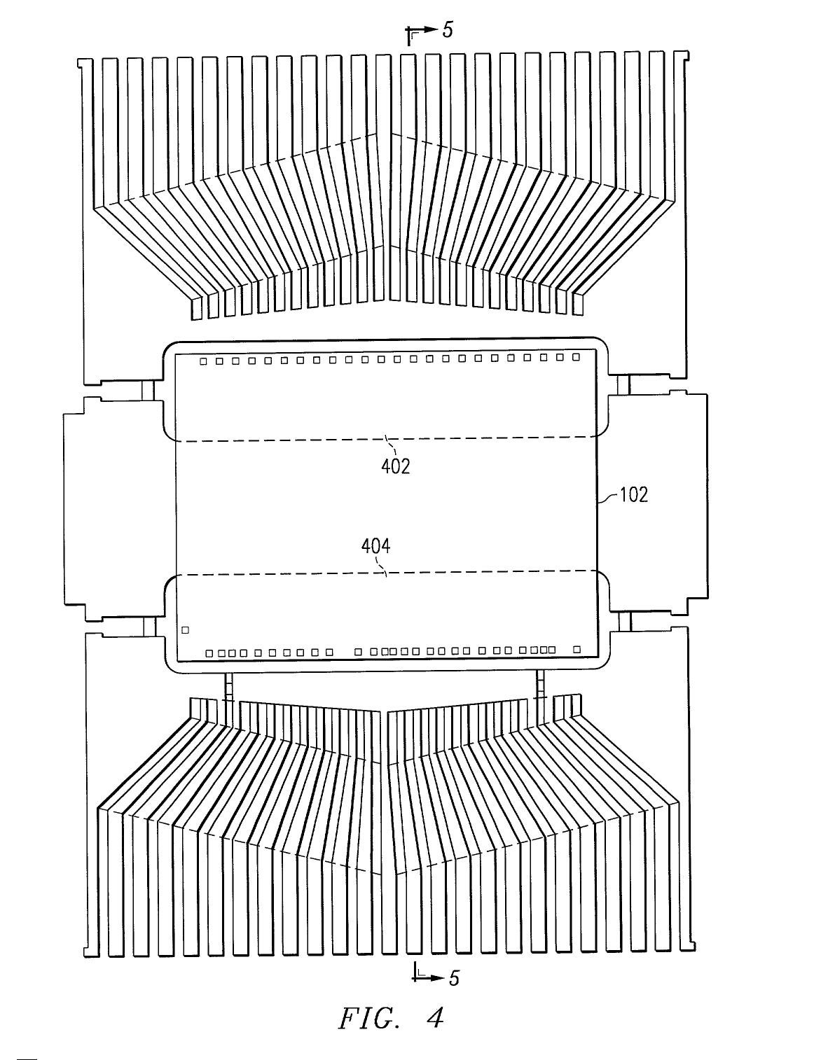

Alternatively, the objectives of reduced die pad area to die area and providing moisture escape paths can be accomplished by providing die pads with areas of relief substantially corresponding to the die pad sections shown in FIGS. 2 and 4. For example, referring to FIG. 6, a die pad can be formed with the regions under the four comers of the die 102 removed. This results in a die pad 702 having a cross-shaped area supporting the die. Similarly, in FIG. 7, the die pad area 702 supporting the die can be a rectangular region over which the die 102 extends. In this case, the regions of relief are along two opposing edges of the die pad. FIG. 8 illustrates the embodiment of FIG. 7 in cross section. It is desirable to minimize the die pad area to die area in these cases as well. As in the embodiments discussed in connection with FIGS. 2 and 4, the preferred die pad area to die size ratio should be in the range of about 0.30 to about 0.50.

In each of the embodiments illustrated herein, a completed integrated circuit can be formed using known techniques. For example, while not shown, the die is generally bonded to the die pad using an adhesive, bonding wires are attached between the die and the packaging leads, and the assembly is encapsulated in an epoxy, plastic or ceramic packaging material.

Although the present invention has been described in connection with certain embodiments thereof, it will be appreciated that various changes and modifications can be made by those skilled in the art without departing from the scope and spirit of the invention as defined by the appended claims.

What is claimed is:

1. A die pad configuration for an integrated circuit having an integrated circuit die, the die pad comprising:
a plurality of die pad regions for supporting the integrated circuit die, each die pad region having an area associated therewith, the die pad regions being arranged in a spaced apart relationship with respect to the die, the total area of the plurality of die pad regions being at most equal to fifty percent (50%)of the area of the die.

2. The die pad configuration of claim 1, wherein the plurality of die pad regions include four die pad regions.

3. The die pad configuration of claim 2, wherein the four die pad regions are spaced apart such that they are each proximate to a corner of the die.

4. The die pad configuration of claim 3 wherein the the total area of the four die pad regions is about 0.32 of the area of the die.

5. The die pad configuration of claim 1, wherein the plurality of die pad regions include two die pad regions.

6. The die pad configuration of claim 5, wherein the two die pad regions are spaced apart such that they are each proximate to an opposing edge of the die.

7. The die pad configuration of claim 6 wherein the area of the two die pad regions is about 0.42 of the area of the die.

8. A die pad for an integrated circuit having an integrated circuit die, the die pad comprising a support portion for supporting the integrated circuit die, the support portion having a plurality of regions of relief therein, the relief regions being arranged in a spaced apart relationship with respect to the die, the support portion having a total area being at most equal to forty percent (40%) of the area of the die.

9. The die pad of claim 8, wherein the plurality of relief regions include four rectangular regions.

10. The die pad of claim 9, wherein the four relief regions are spaced apart such that they are each proximate to a corner of the die.

11. The die pad configuration of claim 8, wherein the plurality of relief regions include two rectangular regions.

12. The die pad of claim 10, wherein the two relief regions are spaced apart such that they are each proximate to an opposing edge of the die.
